(19) United States
(12) Patent Application Publication
(10) Pub. No.: US 2015/0176774 A1
(43) Pub. Date: Jun. 25, 2015

(54) Light Emitting Module and Optical Lens Thereof

(71) Applicant: Lextar Electronics Corporation, Hsinchu (TW)

(72) Inventor: Kuo-Chiang Chen, Hukou Township (TW)

(21) Appl. No.: 14/533,353

(22) Filed: Nov. 5, 2014

(30) Foreign Application Priority Data
Dec. 19, 2013 (TW) 102147188

(51) Int. Cl. F21K 99/00; F21V 5/04; H01L 33/58

(52) U.S. Cl. CPC F21K 9/50; H01L 33/58; F21V 5/048; F21Y 2101/02

(57) ABSTRACT

The disclosure provides an optical lens including a body. The body includes a light-incident surface and a light-emitting surface. The light-emitting surface is located at an outer surface of the body. The light-incident surface is located at a bottom surface of the body. The body includes a concave portion located at the center of the bottom surface. The concave portion is dented from the bottom surface to the light-emitting surface for accommodating a light source, and the surface of the concave portion is the light-incident surface. The light-emitting surface includes a dented center light-emitting zone and an arc-shaped peripheral light-emitting zone. The dented center light-emitting zone is located at a center zone of the outer surface of the body. The dented center light-emitting zone is aligned with the center of the bottom surface of the body and is indented in a direction toward the light-incident surface.

### RELATED APPLICATIONS

This application claims priority to Taiwan Application Serial Number 102147188, filed Dec. 19, 2013, which is herein incorporated by reference.

### BACKGROUND

1. Technical Field

The present disclosure relates to a light emitting module. More particularly, the present disclosure relates to a light emitting module having an optical lens.

2. Description of Related Art

A conventional direct illumination-type LED backlight display has the advantages of high brightness and high contrast. Hence, the direct illumination-type LED backlight display is a key area of industrial research and development. The direct illumination-type LED backlight module encounters limitations as a result of LED emission angle and strength. As a result, the direct illumination-type LED backlight module needs to employ a certain light-mixing distance or a relatively high density of LED distribution, and must use a diffusion plate (diffuser) to fix the problem of brightness nonuniformity (e.g., bright spots and dark zones). Although a wide-angle lens is used to reduce the number of LEDs and to decrease the light-mixing distance, due to the resulting circular-shaped light, dark zones at light gaps are still formed. FIG. 1 is a plan view of a projection light of a conventional light emitting module on a diffusion plate. The light emitting module is used in a direct illumination-type LED backlight display as a backlight module. The light that is projected on the diffusion plate 300 by conventional light-emitting diodes appears as circle light spots 600. A dark zone 620 is formed between the circle light spots 600, and causes a decrease in picture saturation.

### SUMMARY

The disclosure provides an optical lens including a body. The body includes a light-incident surface and a light-emitting surface. The light-emitting surface is located at an outer surface of the body. The light-incident surface is located at a bottom surface of the body. The body includes a concave portion located at the center of the bottom surface. The concave portion is dented from the bottom surface to the light-emitting surface for accommodating a light source, and the surface of the concave portion is the light-incident surface. The light-emitting surface includes a dented center light-emitting zone and an arc-shaped peripheral light-emitting zone. The dented center light-emitting zone is located at a center zone of the outer surface of the body. The dented center light-emitting zone is aligned with the center of the bottom surface of the body and is indented in a direction toward the light-incident surface. A thickness (d1) of the body between the dented center light-emitting zone and the light-incident surface gradually increases outward from the center of the dented center light-emitting zone. The arc-shaped peripheral light-emitting zone is extended between the dented center light-emitting zone and the bottom portion of the body. The shape of the outer-rim of the arc-shaped peripheral light-emitting zone is a square with four arc angles, so that after a light emitted from a light-emitting diode passes through the body. The light is formed into a square projection light.

In an embodiment of the present disclosure, the arc-shaped peripheral light-emitting zone includes a first arc-shaped peripheral light-emitting zone and a second arc-shaped peripheral light-emitting zone. The first arc-shaped peripheral light-emitting zone is connected with the dented center light-emitting zone. The second arc-shaped peripheral light-emitting zone is connected with the first arc-shaped peripheral light-emitting zone and the bottom portion of the body. A thickness (d2) of the body between the first arc-shaped peripheral light-emitting zone and the light-incident surface gradually increases away from the center zone of the body. A thickness (d2′) between the second arc-shaped peripheral light-emitting zone and the light-incident surface gradually decreases away from the center zone of the body.

In an embodiment of the present disclosure, the light-incident surface is an arc-shaped surface.

In an embodiment of the present disclosure, the dented center light-emitting zone is an arc-shaped surface.

In an embodiment of the present disclosure, the light-incident surface has a center of curvature C1. The dented center light-emitting zone has a center of curvature C2, and a vertical projection of the center of curvature C2 coincides with the center of curvature C1. The optical lens has a normal line N1 that passes through the center of curvature C1 and the center of curvature C2. The normal line N1 passes through a center of a light-emitting surface of the light source accommodated within the concave portion. The normal line N1 passes through a virtual plane X1 and a virtual plane Y1. The virtual plane X1 and the virtual plane Y1 are perpendicular to each other and pass through the center of curvature C1 and the center of curvature C2. The virtual plane X1 and the virtual plane Y1 also pass through the arc angles symmetrical to each other about the normal line N1. The virtual plane X1 has a node a and a node b on the boundary of the first arc-shaped peripheral light-emitting zone and the second arc-shaped peripheral light-emitting zone. The virtual plane Y1 has a node c and a node d on the boundary of the first arc-shaped peripheral light-emitting zone and the second arc-shaped peripheral light-emitting zone. The node a and the node b are symmetrical about the normal line N1. The node c and the node d are symmetrical to each other about the normal line N1. A virtual-equal-division plane X2 and a virtual-equal-division plane Y2 bisect an angle between the virtual plane X1 and the virtual plane Y1. The virtual-equal-division plane X2, and the virtual-equal-division plane Y2 are perpendicular to each other. The virtual-equal-division plane X2 and the boundary of the first arc-shaped peripheral light-emitting zone and the second arc-shaped peripheral light-emitting zone have a node m and a node n. The virtual-equal-division plane Y2 and the boundary of the first arc-shaped peripheral light-emitting zone and the second arc-shaped peripheral light-emitting zone have a node o and a node p. The node m, the node n, the node o, and the node p are symmetrical about the normal line N1. A line is formed by connecting the center of the light-emitting surface of the light source accommodated within the concave portion to the node a, the node b, the node c, or the node d. The line and the normal line N1 form an inclined angle α therebetween, where 40°≦α≦70°. A line is formed by connecting the center of the light-emitting surface of the light source accommodated within the concave portion to the node m, the node n, the node o, or the node p. The line and the normal line N1 form an inclined angle β therebetween, where 3°≦α−β≦7.

In an embodiment of the present disclosure, the inclined angle α is 55.

In an embodiment of the present disclosure, a luminosity of the node a, the node b, the node c, or the node d is 1.1˜1.7 times a luminosity of the node m, the node n, the node o, or the node p.

In an embodiment of the present disclosure, a radius of curvature r2 of the dented center light-emitting zone is greater than a radius of curvature r1 of the light-incident surface.

The present disclosure further provides a light emitting module including a substrate, a light source, and an optical lens. The light source is disposed on the substrate. The optical lens is fixed to the substrate by the bottom portion of the body. The light source is accommodated within the concave portion of the bottom surface of the body.

In an embodiment of the present disclosure, the light source is a light-emitting diode.

Accordingly, the light emitting module can produce square-shaped projection light spots connected to each other. When the light emitting module is used with a screen, the light emitting module projects light into a diffusion plate to form the square-shaped projection light spots without any gap therebetween, thus decreasing the dark zones and the requirement for a large number of LEDs.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1 is a plan view of a projection light of a conventional light emitting module on the diffusion plate;

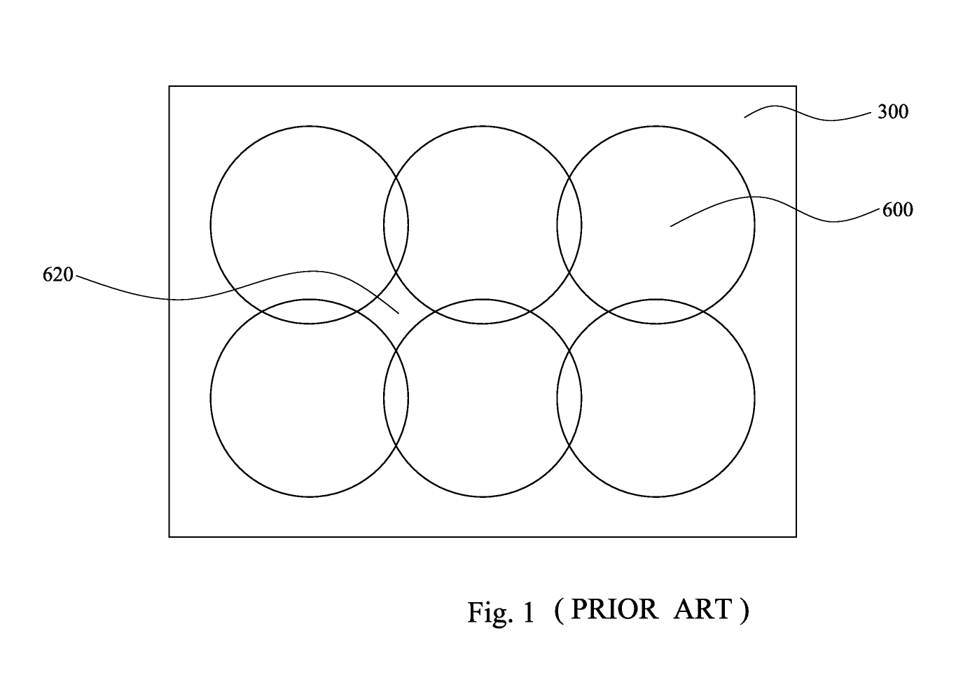

FIG. 2 is a perspective view of a light emitting module according to an embodiment of the present disclosure;

FIG. 3 is a cross-sectional view of the light emitting module in FIG. 2 along line 3-3′;

FIG. 4 is a schematic view of the light emitting module according to an embodiment of the present disclosure;

FIG. 5 is a top view of the light emitting module in FIG. 4;

FIG. 6 is a cross-sectional view of the light emitting module along a virtual plane X1 in FIG. 4;

FIG. 7 is a cross-sectional view of the light emitting module in FIG. 4 along a virtual-equal-division plane X2;

FIG. 8 is a polar graph according to an embodiment of the present is disclosure;

FIG. 9 is a graph showing the relation between an intensity and a degree according to an embodiment of the present disclosure;

FIG. 10 is a side view of a light emitting module used in a table lamp according to another embodiment of the present disclosure; and

FIG. 11 is a schematic view of area A in FIG. 10.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

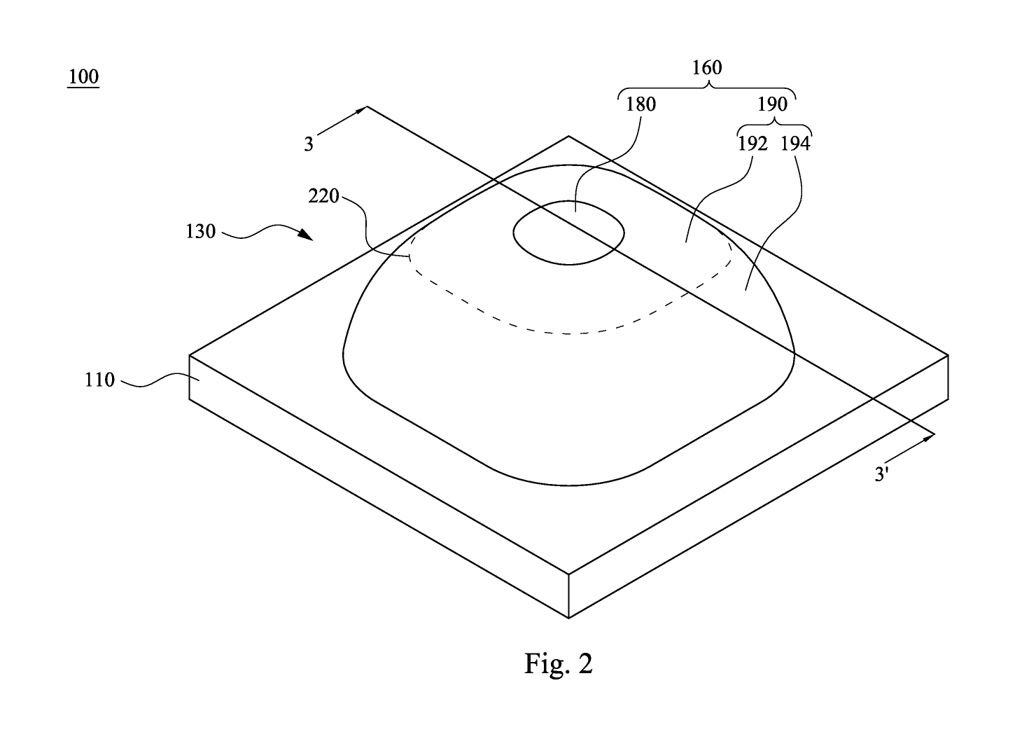

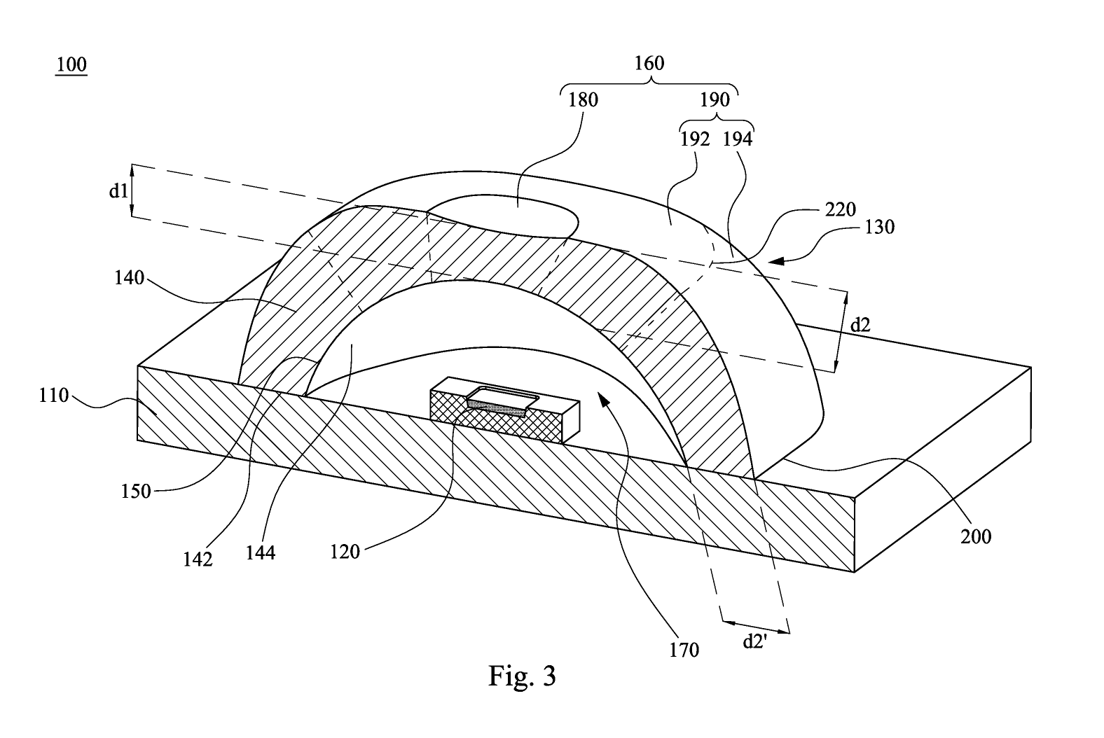

The present disclosure provides a light emitting module that is able to effectively solve the problem of a low picture quality associated with a conventional light emitting module. FIG. 2 is a perspective view of a light emitting module 100 according to an embodiment of the present disclosure. FIG. 3 is a cross-sectional view of the light emitting module 100 in FIG. 2 along line 3-3′. The light emitting module 100 includes a substrate 110, a light source 120, and an optical lens 130. The light source 120 is disposed on the substrate 110. In this embodiment, the light source 120 is a light-emitting diode. The optical lens 130 includes a body 140. The optical lens 130 is fixed on the substrate 110 by a bottom portion 142 of the body 140.

The body 140 of the optical lens 130 includes a light-incident surface 150 and a light-emitting surface 160. The light-emitting surface 160 is located on the outer surface of the body 140. The light-incident surface 150 is located on a bottom surface 144 of the body 140. The body 140 includes a concave portion 170 located at the center of the bottom surface 144. The concave portion 170 is indented from the bottom surface 144 in a direction toward the light-emitting surface 160, and is used for accommodating the light source 120. The light-incident surface 150 is formed through such a configuration and defines the concave portion 170. The light-emitting surface 160 includes a dented center light-emitting zone 180 and an arc-shaped peripheral light-emitting zone 190. The dented center light-emitting zone 180 is located at a center of the outer surface of the body 140. The dented center light-emitting zone 180 is aligned with the center of the bottom surface 144 of the body 140 and is indented in a direction toward the light-incident surface 150. The arc-shaped peripheral light-emitting zone 190 is extended between the dented center light-emitting zone 180 and the bottom portion 142 of the body 140. In this embodiment, the light-incident surface 150 is an arc-shaped surface. In this embodiment, the dented center light-emitting zone 180 is an arc-shaped surface.

A thickness d1 of the body 140 between the dented center light-emitting zone 180 and the light-incident surface 150 gradually increases outward from the center of the dented center light-emitting zone 180. That is, the thickness d1 of the body 140 increases as the arc-shaped peripheral light-emitting zone 190 is approached from the center of the dented center light-emitting zone 180.

The arc-shaped peripheral light-emitting zone 190 includes a first arc-shaped peripheral light-emitting zone 192 and a second arc-shaped peripheral light-emitting zone 194. The first arc-shaped peripheral light-emitting zone 192 is connected with the dented center light-emitting zone 180. The second arc-shaped peripheral light-emitting zone 194 is connected with the first arc-shaped peripheral light-emitting zone 192 and the bottom portion 142 of the body 140. The first arc-shaped peripheral light-emitting zone 192 and the second arc-shaped peripheral light-emitting zone 194 are separated by a boundary 220. A thickness d2 of the body 140 between the first arc-shaped peripheral light-emitting zone 192 and the light-incident surface 150 gradually increases in a direction away from the center zone of the body 140. That is, the thickness d2 of the first arc-shaped peripheral light-emitting zone 192 increases in a direction away from the center light-emitting zone 180. A thickness d2′ between the second arc-shaped peripheral light-emitting zone 194 and the light-incident surface 150 gradually decreases in a direction away from the center zone of the body 140.

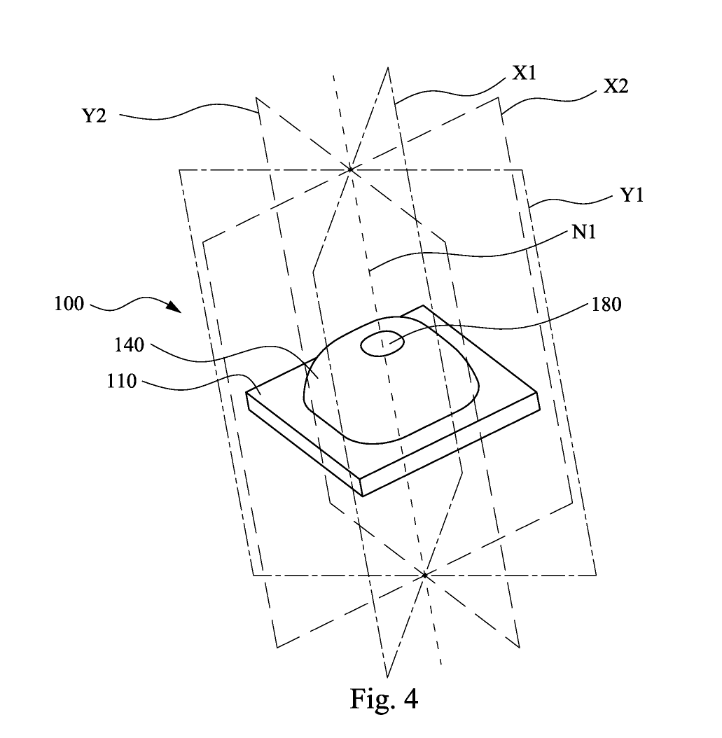

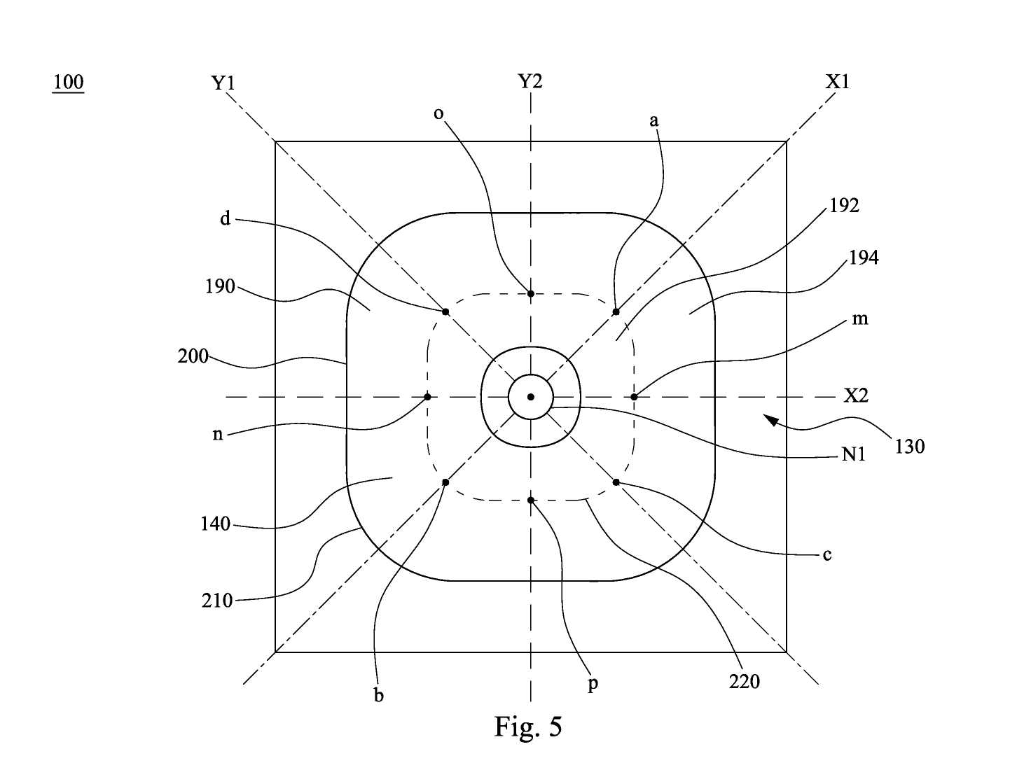

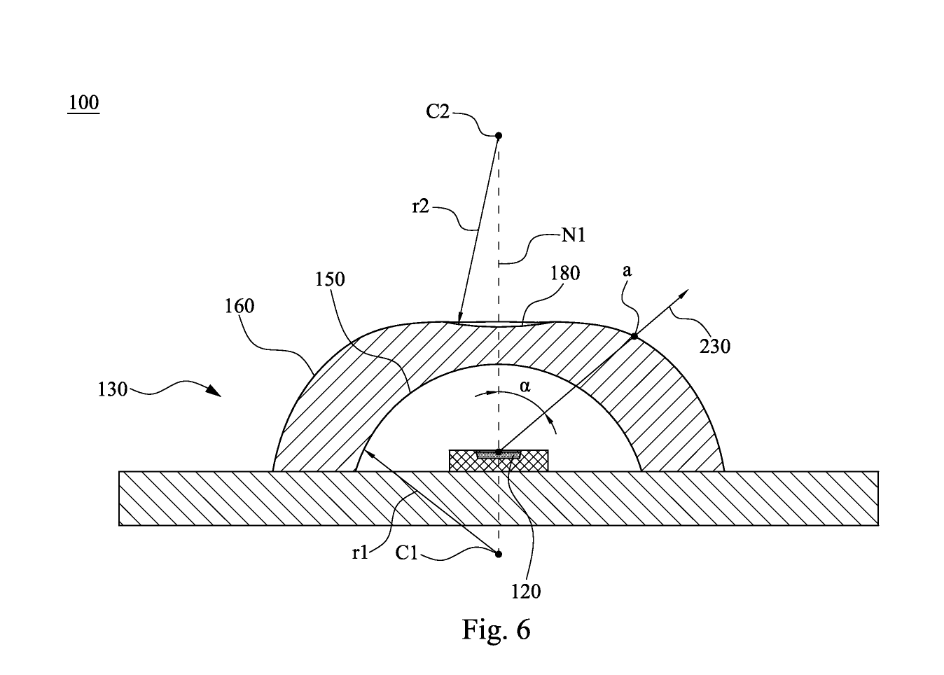

FIG. 4 is a schematic view of the light emitting module 100 according to an embodiment of the present disclosure. FIG. 5 is a top view of the light emitting module 100 in FIG. 4. FIG. 6 is a cross-sectional view of the light emitting module 100 along a virtual plane X1 in FIG. 4. In this embodiment, the light-incident surface 150 has a center of curvature C1, and the dented center light-emitting zone 180 has a center of curvature C2. A vertical projection of the center of curvature C2 coincides with the center of curvature C1. A radius of curvature r2 of the dented center light-emitting zone 180 is greater than a radius of curvature r1 of the light-incident surface 150. The optical lens 130 has a normal line N1 that passes through the center of curvature C1 and the center of curvature C2.

The body 140 includes the virtual plane X1 and a virtual plane Y1. The virtual plane X1 and the virtual plane Y1 are perpendicular to each other and pass through the center of curvature C1 and the center of curvature C2. The virtual plane X1 and the virtual plane Y1 also pass through arc angles 210 symmetrical to each other about the normal line N1. That is, the virtual plane X1 passes through the arc angles 210 symmetrical to each other about the normal line N1 and also passes through N1. The virtual plane X1 has a node a and a node b on the boundary 220 of the first arc-shaped peripheral light-emitting zone 192 and the second arc-shaped peripheral light-emitting zone 194. The node a and the node b are symmetrical about the normal line N1. A line 230 is formed by connecting the center of the light-emitting surface 160 of the light source 120 to the node a, the node b, the node c, or the node d. The line 230 and the normal line N1 form an inclined angle a therebetween, and 40°≦α≦70°. The physical significance of the inclined angle α and the body 140 is that on the virtual plane X1 or the virtual plane Y1, the body 140 of the optical lens 130 has the greatest thickness of the body 140 with angle α, such that the line 230 with the inclined angle α has the best concentrating ability and light intensity.

In this embodiment, the inclined angle α is 55 degrees. That is, when used for a screen, the optical lens 130 controls the divergence area of a projection light accurately. Compared to the conventional light emitting module, the light emitting module 100 can make the picture more homogeneous. On the other hand, a projection light of the light emitting module 100 decreases when the angle is greater than 55 degrees. In comparison with the conventional light emitting module, a projection light of the light emitting module 100 does not irradiate into a user's eyes, such that the invention can be used in a glare-proof table lamp without an optical filter. Therefore, costs are minimized and the market for such a table lamp is increased.

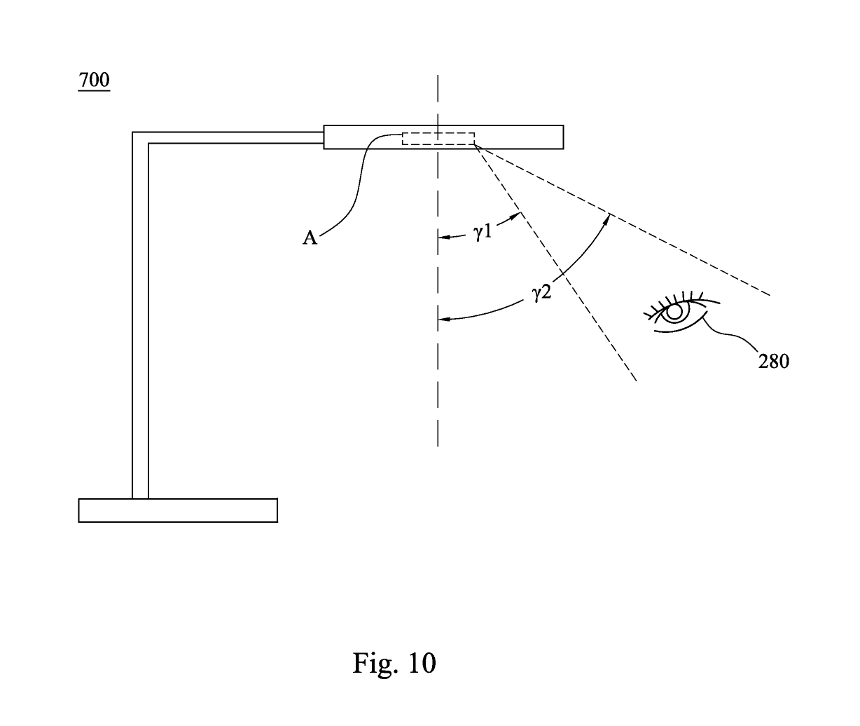

Reference is made additionally to FIG. 10. The line 230 passing through the node b is not described in FIG. 6. Because the node a and the node b are symmetrical with respect to the normal line N1, the operational principles as described above are the same. Hence, the line 230 passing through the node b is not described again. Furthermore, the optical lens 130 has circular symmetry when the normal line N1 is taken as a symmetry center. Therefore, the cross-sectional view along the virtual plane X1 and the virtual plane Y1 are the same, and the operational principles are again the same. Consequently, the cross-sectional view along the virtual plane Y1 is not shown, and the line 230 passing through the node c and node d will not be described. In FIG. 5, the shape surrounded by an outer-rim 200 of the arc-shaped peripheral light-emitting zone 190 is a rectangle with four arc angles 210. After the light emitted from the light source 120 (see FIG. 6) passes through the body 140, the light forms a square projection light.

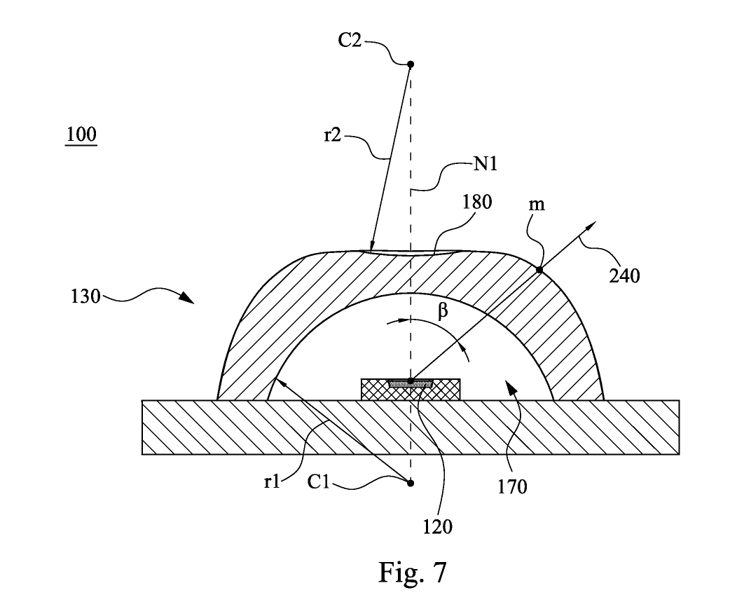

FIG. 7 is a cross-sectional view of the light emitting module 100 in FIG. 4 along a virtual-equal-division plane X2. Referring to FIG. 4, FIG. 5 and FIG. 7. The virtual-equal-division plane X2 and the virtual-equal-division plane Y2 are disposed between the virtual plane X1 and the virtual plane Y1. The virtual-equal-division plane X2 and the virtual-equal-division plane Y2 bisect an angle between the virtual plane X1 and the virtual plane Y1. The virtual-equal-division plane X2 and the virtual-equal-division plane Y2 are perpendicular to each other. The virtual-equal-division plane X2 and the boundary 220 of the first arc-shaped peripheral light-emitting zone 192 and the second arc-shaped peripheral light-emitting zone 194 have a node m and a node n. The virtual-equal-division plane Y2 and the boundary 220 of the first arc-shaped peripheral light-emitting zone 192 and the second arc-shaped peripheral light-emitting zone 194 have a node o and a node p. The nodes m, n, o, and p are symmetrical about the normal line N1. A line 240 is formed by connecting the center of the light-emitting surface 160 of the light source 120 accommodated within the concave portion 170 to the node a, b, c, or d. The line 240 and the normal line N1 form an inclined angle β therebetween, where 3°≦α−β≦7°. The physical significance of the inclined angle β and the body 140 is that on the virtual-equal-division plane X2 or the virtual-equal-division plane Y2, the body 140 has a greatest thickness with the inclined angle β.

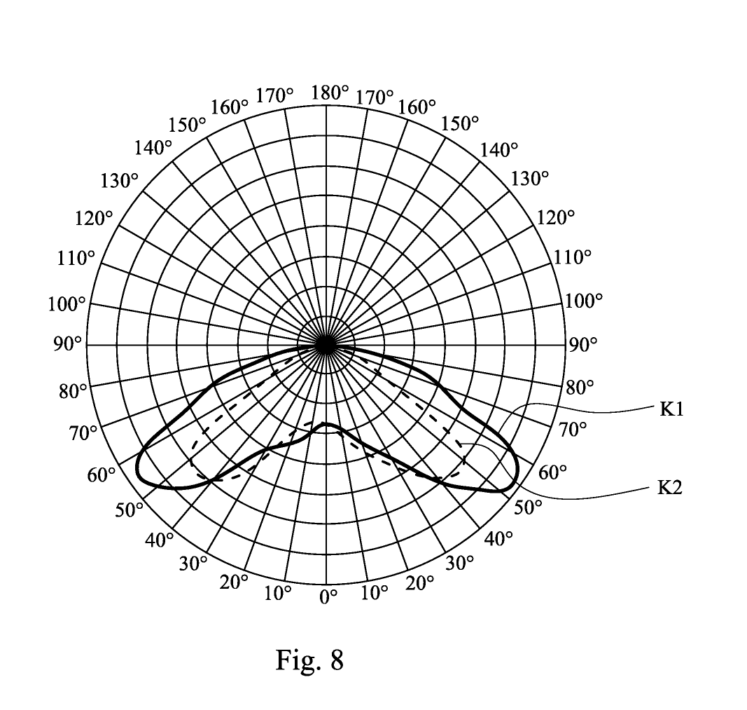

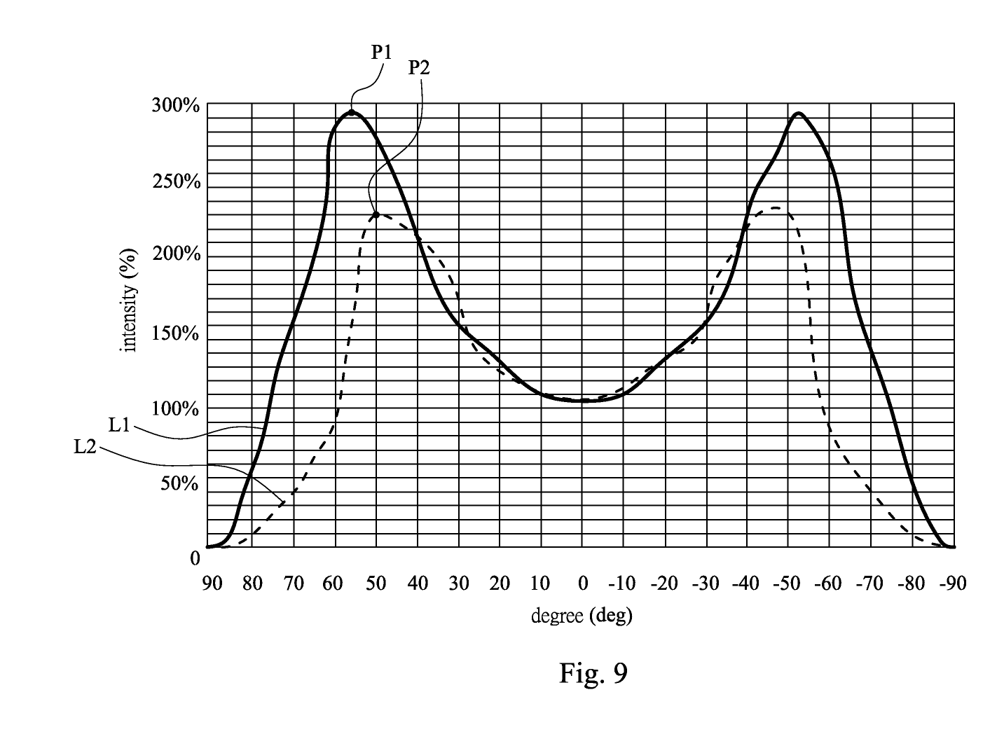

FIG. 8 is a polar graph according to an embodiment of the present disclosure. FIG. 9 is a graph showing the relation between an intensity and a degree according to an embodiment of the present disclosure. Reference is made to FIG. 4, FIG. 8, and FIG. 9. The curve L1 is the light intensity of the virtual plane X1 or the virtual plane Y1. A point P1 is the light intensity of the node a, b, c, or d. The curve L2 is the light intensity of the virtual-equal-division plane X2, or the virtual-equal-division plane Y2. A point P2 is the light intensity of the node m, n, o, or p. In this embodiment, the light intensity of the point P1 is 1.1˜1.7 times the light intensity of the point P2. That is, when the light source 120 (see FIG. 7) emits a light through the body 140 into the node a, b, c, or d, the light intensity of the light is 1.1˜1.7 times the light intensity of the node m, n, o, or p. The polar graph of this invention is such that the light of the light source 120 (see FIG. 7) forms a square-shaped projection light. Because the distance between four angles and a side of a rectangle is greater than the distance between the center and a side of a rectangle, the light intensity of the node a, b, c, or d close to the arc angles 210 is greater than the light intensity of the node m, n, o, or p close to a side of the body 140. As a result, the light intensity of the angle in a square-shaped projection light projected by the optical lens 130 can be equal to the light intensity of the four sides in the square-shaped projection light, such that the light intensity of the square-shaped projection light is homogeneous.

The curve L1 reveals that the greatest light intensity measured along the virtual plane X1 or the virtual plane Y1 is between 40 and 70 (i.e., 40°≦α≦70°, see FIG. 6). A comparison of the curve L1 and the curve L2 reveals that the greatest light intensity measured along the virtual plane X2 or the virtual plane Y2 has a difference of 3 to 7 degrees (i.e., 3°≦α−β≦7°, see FIG. 6 and FIG. 7). In this embodiment, the light intensity of the curve L1 decreases at 55 degrees. In comparison with the conventional light emitting module, a projection light projected by the light emitting module 100 does not irradiate into a user's eyes, such that the invention can be used in a glare-proof table lamp without an optical filter. Therefore, costs are minimized and the market for such a table lamp is increased. Details are described with reference to FIG. 10.

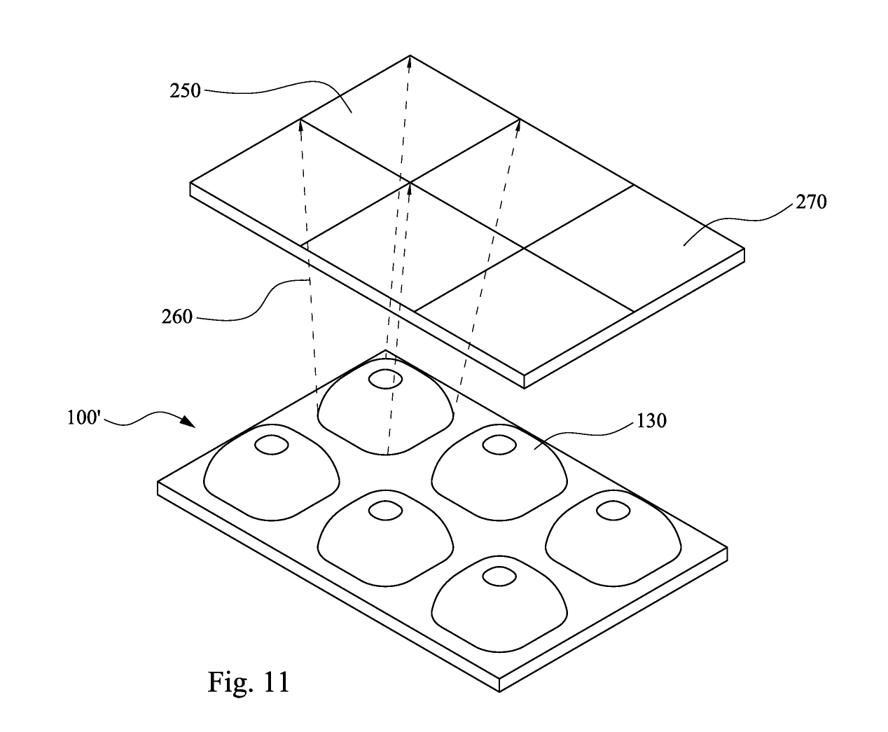

FIG. 10 is a side view of a light emitting module 100′ (see FIG. 11) used in a table lamp 700 according to another embodiment of the present disclosure. FIG. 11 is a schematic view of area A in FIG. 10. A projection light 250 projected by a light emitting module 100′ has an effective angle γ1 of about 55 degrees (see FIG. 9 and the related description). This indicates that the light intensity decreases significantly beyond 55 degrees. In comparison with a projection light of the conventional method in which the effective angle γ2 is generally 70 degrees, the projection light 250 of the light emitting module 100′ has a smaller range of effective angle γ1. Consequently, when the light emitting module 100′ is used in the table lamp 700, the light of the table lamp 700 does not emit into a user's eyes 280. Therefore, the light does not result in glare for the user. The light emitting module 100′ forms the square-shaped projection light 250 connected to each other. When the light emitting module 100′ is used with a screen (e.g., a back light source), a light 260 of the light emitting module 100′ is projected onto a diffusion plate 270 to create the square-shaped projection light 250, and the projection light 250 is positioned immediately adjacent to each other without any gaps, bright spots, or dark zones therebetween. Accordingly, in comparison with the circular conventional projection light, the projection light 250 of the light emitting module 100′ is more homogeneous. Moreover, in comparison with the conventional light emitting module, the projection light 250 of the light emitting module 100′ does not irradiate into a user's eye, such that the invention can be used in a glare-proof table lamp without an optical filter. Therefore, costs are minimized and the market for such a table lamp is increased. The projection light 250 of the light emitting module 100′ is also more homogeneous. In conclusion, the light emitting module 100′ is commercially valuable.

Accordingly, the light emitting module can produce square-shaped projection light positioned immediately adjacent to each other. When the light emitting module is used with a screen, the light emitting module projects light into a diffusion plate to form the square-shaped projection light without any gaps therebetween, thus decreasing dark zones and the requirement for a large number of LEDs.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. An optical lens, comprising:
a body comprising a light-incident surface and a light-emitting surface, the light-emitting surface being located at an outer surface of the body, the light-incident surface being located at a bottom surface of the body, the body comprising a concave portion located at the center of the bottom surface, the concave portion being dented from the bottom surface to the light-emitting surface for accommodating a light source, and the surface of the concave portion being the light-incident surface;
wherein the light-emitting surface comprises:
a dented center light-emitting zone located at a center zone of the outer surface of the body, the dented center light-emitting zone being aligned with the center of the bottom surface of the body and being indented in a direction toward the light-incident surface, wherein a thickness (d1) of the body between the dented center light-emitting zone and the light-incident surface gradually increases outward from the center of the dented center light-emitting zone; and
an arc-shaped peripheral light-emitting zone extended between the dented center light-emitting zone and the bottom portion of the body, wherein the shape of the outer-rim of the arc-shaped peripheral light-emitting zone is a square with four arc angles, such that after a light emitted from a light-emitting diode passes through the body, the light is formed into a square projection light.

2. The optical lens of claim 1, wherein the arc-shaped peripheral light-emitting zone comprises a first arc-shaped peripheral light-emitting zone and a second arc-shaped peripheral light-emitting zone, the first arc-shaped peripheral light-emitting zone is connected with the dented center light-emitting zone, the second arc-shaped peripheral light-emitting zone is connected with the first arc-shaped peripheral light-emitting zone and the bottom portion of the body, a thickness (d2) of the body between the first arc-shaped peripheral light-emitting zone and the light-incident surface gradually increases away from the center zone of the body, and a thickness (d2′) between the second arc-shaped peripheral light-emitting zone and the light-incident surface gradually decreases away from the center zone of the body.

3. The optical lens of claim 2, wherein the light-incident surface is an arc-shaped surface.

4. The optical lens of claim 3, wherein the dented center light-emitting zone is an arc-shaped surface.

5. The optical lens of claim 2, wherein the light-incident surface has a center of curvature C1, the dented center light-emitting zone has a center of curvature C2, a vertical projection of the center of curvature C2 coincides with the center of curvature C1, the optical lens has a normal line N1 passing through the center of curvature C1 and the center of curvature C2, the normal line N1 passes through a center of a light-emitting surface of the light source accommodated within the concave portion, the normal line N1 passes through a virtual plane X1 and a virtual plane Y1, the virtual plane X1 and the virtual plane Y1 are perpendicular to each other and pass through the center of curvature C1 and the center of curvature C2, the virtual plane X1 and the virtual plane Y1 also pass through the arc angles symmetrical to each other about the normal line N1, and the virtual plane X1 has a node a and a node b on the boundary of the first arc-shaped peripheral light-emitting zone and the second arc-shaped peripheral light-emitting zone, the virtual plane Y1 has a node c and a node d on the boundary of the first arc-shaped peripheral light-emitting zone and the second arc-shaped peripheral light-emitting zone, the node a and the node b are symmetrical about the normal line N1, the node c and the node d are symmetrical to each other about the normal line N1, a virtual-equal-division plane X2 and a virtual-equal-division plane Y2 bisect an angle between the virtual plane X1 and the virtual plane Y1, wherein the virtual-equal-division plane X2, and the virtual-equal-division plane Y2 are perpendicular to each other, the virtual-equal-division plane X2 and the boundary of the first arc-shaped peripheral light-emitting zone and the second arc-shaped peripheral light-emitting zone have a node m and a node n, the virtual-equal-division plane Y2 and the boundary of the first arc-shaped peripheral light-emitting zone and the second arc-shaped peripheral light-emitting zone have a node o and a node p, and the node m, the node n, the node o, and the node p are symmetrical about the normal line N1;
wherein a line is formed by connecting the center of the light-emitting surface of the light source accommodated within the concave portion to the node a, the node b, the node c, or the node d, the line and the normal line N1 forming an inclined angle α therebetween, where 40°≦α≦70°;
wherein a line is formed by connecting the center of the light-emitting surface of the light source accommodated within the concave portion to the node m, the node n, the node o, or the node p, the line and the normal line N1 form an inclined angle β therebetween, where 3°≦α−β≦7°.

6. The optical lens of claim 5, wherein the inclined angle α is 55°.

7. The optical lens of claim 5, wherein a luminosity of the node a, the node b, the node c, or the node d is 1.1˜1.7 times a luminosity of the node m, the node n, the node o, or the node p.

8. The optical lens of claim 5, wherein a radius of curvature r2 of the dented center light-emitting zone is greater than a radius of curvature r1 of the light-incident surface.

9. A light emitting module, comprising:
a substrate;
a light source disposed on the substrate; and
an optical lens, comprising:
a body comprising a light-incident surface and a light-emitting surface, the light-emitting surface being located at an outer surface of the body, the light-incident surface being located at a bottom surface of the body, the body comprising a concave portion located at the center of the bottom surface, the concave portion being dented from the bottom surface to the light-emitting surface for accommodating a light source, and the surface of the concave portion being the light-incident surface;
wherein the light-emitting surface comprises:
a dented center light-emitting zone located at a center zone of the outer surface of the body, the dented center light-emitting zone being aligned with the center of the bottom surface of the body and being indented in a direction toward the light-incident surface, wherein a thickness (d1) of the body between the dented center light-emitting zone and the light-incident surface gradually increases outward from the center of the dented center light-emitting zone; and
an arc-shaped peripheral light-emitting zone extended between the dented center light-emitting zone and the bottom portion of the body, wherein the shape of the outer-rim of the arc-shaped peripheral light-emitting zone is a square with four arc angles, so that after a light emitted from a light-emitting diode passes through the body, the light is formed into a square projection light
wherein the optical lens is fixed to the substrate by the bottom portion of the body, and the light source is accommodated within the concave portion of the bottom surface of the body.

10. The light emitting module of claim 9, wherein the light source is a light-emitting diode.
